(19) United States
(12) Patent Application Publication
(10) Pub. No.: US 2017/0301845 A1
(43) Pub. Date: Oct. 19, 2017

(54) P-TYPE THERMOELECTRIC MATERIAL, THERMOELECTRIC ELEMENT AND METHOD FOR PRODUCING P-TYPE THERMOELECTRIC MATERIAL

(71) Applicants: MITSUBA Corporation, Kiryu-shi, Gunma (JP); National Institute for Materials Science, Tsukuba-shi, Ibaraki (JP)

(72) Inventors: Satoki TADA, Kiryu-shi (JP); Yukihiro ISODA, Tsukuba-shi (JP)

(21) Appl. No.: 15/515,851

(22) PCT Filed: Sep. 18, 2015
(86) PCT No.: PCT/JP2015/076748

§ 371 Date: Mar. 30, 2017

(30) Foreign Application Priority Data
Oct. 3, 2014 (JP) 2014-205229

(51) Int. Cl. H01L 35/22; C30B 1/02; C01G 19/00

(52) U.S. Cl. CPC H01L 35/22; C01G 19/006; C30B 1/02

(57) ABSTRACT

A p-type thermoelectric material according to one aspect of the present invention is configured such that at least any one of a Mg site, a Si site, a Sn site and/or a Ge site in a compound composed of magnesium (Mg), silicon (Si), tin (Sn) and germanium (Ge) is substituted with any one or more elements selected from the group consisting of alkali metals of group 1A and gold (Au), silver (Ag), copper (Cu), zinc (Zn), calcium (Ca) and gallium (Ga) of group 1B.

### TECHNICAL FIELD

The present invention relates to a p-type thermoelectric material, a thermoelectric element and a method for producing a p-type thermoelectric material.

### BACKGROUND ART

In recent years, thermoelectric conversion for converting thermal energy and electric energy by utilizing the Seebeck effect and Peltier effect has been attracting attention as a technology for utilizing energy highly efficiently.

For thermoelectric conversion, a thermoelectric material which is a material capable of converting thermal energy and electric energy to each other is used.

As a thermoelectric material, Mg—Si—Sn-based, Bi—Te-based and Pb—Te-based materials, and the like have been known (for example, see Patent Document 1).

Bi—Te-based and Pb—Te-based materials are expensive and also require careful handling because they use highly rare and hazardous elements. On the other hand, Mg—Si—Sn based materials are excellent in terms of cost and safety because they do not use highly rare and hazardous elements.

Although the Mg—Si—Sn based thermoelectric materials are often used as n-type thermoelectric materials, they have been reported to exhibit p-type characteristics depending on their compositions (for example, see Patent Document 2 and Patent Document 3).

### DOCUMENT OF RELATED ART

### Patent Documents

[Patent Document 1] Japanese Unexamined Patent Application, First Publication No. 2005-133202

[Patent Document 2] Japanese Patent No. 5274146

[Patent Document 3] Japanese Unexamined Patent Application, First Publication No. 2011-151329

### SUMMARY OF INVENTION

### Technical Problem

However, although n-type thermoelectric materials exhibiting high thermoelectric performance have been known, as for p-type thermoelectric materials, their thermoelectric performance has not necessarily been sufficient.

The present invention takes the above circumstances into consideration, with an object of providing a thermoelectric material excellent in performance as a p-type thermoelectric material and a production method thereof.

### Solution to Problem

As a result of intensive investigations, the inventors of the present invention have found that high thermoelectric performance can be achieved by substituting at least any one of a Mg site, a Si site, a Sn site and/or a Ge site of a compound composed of magnesium (Mg), silicon (Si), tin (Sn) and germanium (Ge) with any one or more elements selected from the group consisting of alkali metals of group 1A and gold (Au), silver (Ag), copper (Cu), zinc (Zn), calcium (Ca) and gallium (Ga) of group 1B, thus completing the present invention.

That is, in order to solve the above problems, the present invention adopts the following means.

(1) A p-type thermoelectric material according to one aspect of the present invention is configured such that at least any one of a Mg site, a Si site, a Sn site and/or a Ge site of a compound represented by the following general formula (1) which is composed of magnesium (Mg), silicon (Si), tin (Sn) and germanium (Ge) is substituted with any one or more elements selected from the group consisting of alkali metals of group 1A and gold (Au), silver (Ag), copper (Cu), zinc (Zn), calcium (Ca) and gallium (Ga) of group 1B:

Mg_{A}(Si_{X}Sn_{Y}Ge_{Z}) (1)

provided that relationships represented by formulas: 1.98≦A≦2.01, 0.00<X≦0.25, 0.60≦Y≦0.95, Z>0, X+Y+Z=1 and −1.00X+0.40≧Z≧−2.00X+0.10 (0.00<X≦0.25), −1.00Y+1.00≧Z≧−1.00Y+0.75 (0.60≦Y≦0.90), −2.00Y+1.90≧Z≧−1.00Y+0.75 (0.90<Y≦0.95) are satisfied.

(2) In the p-type thermoelectric material according to the above (1), it is preferable that the compound represented by the aforementioned general formula (1) is multiply substituted with silver (Ag) and an alkali metal of group 1A and/or gold (Au), copper (Cu), zinc (Zn), calcium (Ca) and gallium (Ga) of group 1B.

(3) In the p-type thermoelectric material according to any one of the above (1) and (2), it is preferable that an element to be substituted is silver (Ag).

(4) In the p-type thermoelectric material according to any one of the above (1) to (3), an element to be substituted may be added at 5,000 ppm to 50,000 ppm.

(5) In the p-type thermoelectric material according to any one of the above (1) to (4), at least any one of the Mg site, the Si site, the Sn site and/or the Ge site of the compound represented by the aforementioned general formula (1) may be substituted with any two or more elements selected from the group consisting of alkali metals of group 1A and gold (Au), silver (Ag), copper (Cu), zinc (Zn), calcium (Ca) and gallium (Ga) of group 1B.

(6) A method for producing a p-type thermoelectric material according to one aspect of the present invention is configured to include a step of accommodating magnesium (Mg), silicon (Si), tin (Sn), germanium (Ge) and at least any one of the group consisting of alkali metals of group 1A and gold (Au), silver (Ag), copper (Cu), zinc (Zn), calcium (Ca) and gallium (Ga) of group 1B as a substitution element in a heating member; a step of heating the aforementioned heating member to synthesize a solid solution; and a step of pulverizing and further pressurizing and sintering the aforementioned solid solution, so that a thermoelectric material in which any one of a Mg site, a Si site, a Sn site and/or a Ge site of a compound represented by the following general formula (1) composed of magnesium (Mg), silicon (Si), tin (Sn) and germanium (Ge) is substituted with the aforementioned substitution element is produced:

Mg_{A}(Si_{X}Sn_{Y}Ge_{Z}) (1)

provided that relationships represented by formulas: 1.98≦A≦2.01, 0.00<X≦0.25, 0.60≦Y≦0.95, Z>0, X+Y+Z=1 and −1.00X+0.40≧Z≧−2.00X+0.10 (0.00<X≦0.25), −1.00Y+1.00≧Z≧−1.00Y+0.75 (0.60≦Y≦0.90), −2.00Y+1.90≧Z≧−1.00Y+0.75 (0.90<Y≦0.95) are satisfied.

(7) A p-type thermoelectric element according to one aspect of the present invention includes the p-type thermoelectric material according to any one of the above (1) to (5).

### Advantageous Effects of Invention

In the p-type thermoelectric member according to one aspect of the present invention, at least any one of a Mg site, a Si site, a Sn site and/or a Ge site of a compound composed of magnesium (Mg), silicon (Si), tin (Sn) and germanium (Ge) is substituted with any one or more elements selected from the group consisting of alkali metals of group 1A and gold (Au), silver (Ag), copper (Cu), zinc (Zn), calcium (Ca) and gallium (Ga) of group 1B. For this reason, high thermoelectric performance can be achieved.

A method for producing a p-type thermoelectric material according to one aspect of the present invention includes a step of accommodating magnesium (Mg), silicon (Si), tin (Sn), germanium (Ge) and at least any one of the group consisting of alkali metals of group 1A and gold (Au), silver (Ag), copper (Cu), zinc (Zn), calcium (Ca) and gallium (Ga) of group 1B as a substitution element in a heating member; a step of heating the aforementioned heating member to synthesize a solid solution; and a step of pulverizing and further pressurizing and sintering the aforementioned solid solution. According to this method, a thermoelectric material in which at least any one of a Mg site, a Si site, a Sn site and/or a Ge site of a compound composed of magnesium (Mg), silicon (Si), tin (Sn) and germanium (Ge) is substituted with any one or more elements selected from the group consisting of alkali metals of group 1A and gold (Au), silver (Ag), copper (Cu), zinc (Zn), calcium (Ca) and gallium (Ga) of group 1B can be homogeneously produced.

### BRIEF DESCRIPTION OF DRAWINGS

FIG. 1 shows a crystal structure of a quaternary compound composed of magnesium (Mg), silicon (Si), tin (Sn) and germanium (Ge).

FIG. 2 is a diagram showing regions exhibiting p-type conduction and n-type conduction in a quaternary compound of Mg, Si, Sn and Ge.

FIG. 3 shows a relationship between the compositions of Ge and Si with respect to the conduction types.

FIG. 4 shows a relationship between the compositions of Ge and Sn with respect to the conduction types.

FIG. 5 is a flowchart showing a procedure of a method for producing a thermoelectric material.

FIG. 6 is a schematic view showing a state of installation of raw materials in producing a solid solution.

FIG. 7 shows the X-ray diffraction results of the thermoelectric material of Example 1.

FIG. 8 shows the results of the temperature dependence of the electrical resistivity of the thermoelectric materials of Comparative Examples 2 to 6.

FIG. 9 shows the results of the temperature dependence of the electrical resistivity of the thermoelectric materials of Example 1 and Comparative Example 1.

FIG. 10 shows the temperature dependence of the thermal conductivities of the thermoelectric materials of Comparative Examples 2 to 6.

FIG. 11 shows the results of the temperature dependence of the thermal conductivities of the thermoelectric materials of Example 1 and Comparative Example 1.

FIG. 12 shows the results of the temperature dependence of the Seebeck coefficients of the thermoelectric materials of Comparative Examples 2 to 6.

FIG. 13 shows the results of the temperature dependence of the Seebeck coefficients of the thermoelectric materials of Example 1 and Comparative Example 1.

FIG. 14 shows the results of the temperature dependence of the dimensionless figure of merit ZT of Example 1, Comparative Example 1 and Comparative Example 2.

FIG. 15 shows the results of the temperature dependence of the electrical resistivity of Examples 1 to 4.

FIG. 16 shows the results of the temperature dependence of the Seebeck coefficient of Examples 1 to 4.

FIG. 17 shows the results of the temperature dependence of the thermal conductivity of Examples 1 to 4.

FIG. 18 shows the results of the temperature dependence of the dimensionless figure of merit ZT of Examples 1 to 4.

### DESCRIPTION OF EMBODIMENTS

Hereinafter, configurations of the p-type thermoelectric material and the method for producing a p-type thermoelectric material to which the present invention is applied will be described. In the drawings used in the following description, the characteristic portions and components may be enlarged for easier understanding of characteristic features as a matter of convenience, and the dimensional ratio of each constituent element is not necessarily the same as the actual dimensional ratio. Materials, dimensions, and the like illustrated in the following description are merely examples, and the present invention is not limited thereto and can be carried out with appropriate modifications without departing from the gist of the invention. The p-type thermoelectric material and the method for producing a p-type thermoelectric material according to one aspect of the present invention may include a constituent element which is not described below within a range that does not impair the effects of the present invention.

(p-Type Thermoelectric Material)

A p-type thermoelectric material according to one aspect of the present invention is obtained by substituting at least any one of the Mg site, the Si site, the Sn site and/or the Ge site of a compound represented by the following general formula (1) which is composed of magnesium (Mg), silicon (Si), tin (Sn) and germanium (Ge) with any one or more elements selected from the group consisting of alkali metals of group 1A and gold (Au), silver (Ag), copper (Cu), zinc (Zn), calcium (Ca) and gallium (Ga) of group 1B:

Mg_{A}(Si_{X}Sn_{Y}Ge_{Z}) (1)

provided that relationships represented by formulas: 1.98≦A≦2.01, 0.00<X≦0.25, 0.60≦Y≦0.95, Z>0, X+Y+Z=1 and −1.00X+0.40≧Z≧−2.00X+0.10 (0.00<X≦0.25), −1.00Y+1.00≧Z≧−1.00Y+0.75 (0.60≦Y≦0.90), −2.00Y+1.90≧Z≧−1.00Y+0.75 (0.90<Y≦0.95) are satisfied.

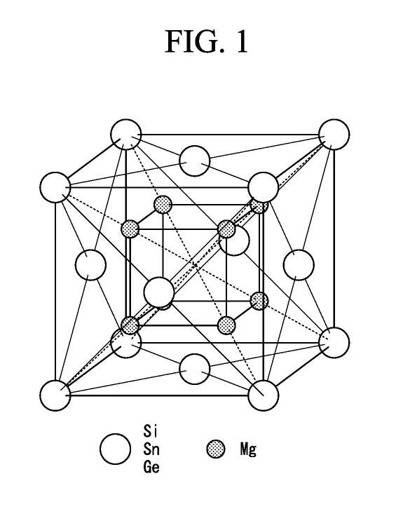

FIG. 1 shows a crystal structure of a quaternary compound composed of magnesium (Mg), silicon (Si), tin (Sn) and germanium (Ge). The compound composed of magnesium (Mg), silicon (Si), tin (Sn) and germanium (Ge) has an inverse fluorite structure.

In the p-type thermoelectric material according to one aspect of the present invention, the compound composed of magnesium (Mg), silicon (Si), tin (Sn) and germanium (Ge) and has this inverse fluorite structure is used as a basic structure. A p-type thermoelectric material composed of a quaternary compound using such four elements is capable of reducing the thermal conductivity as compared with a ternary compound of magnesium (Mg), silicon (Si) and tin (Sn) which has been studied conventionally (Patent Documents 2 and 3).

The reason why the thermal conductivity can be reduced by using the quaternary compound, as compared with the ternary compound, will be described below. As compared with the ternary compound, the quaternary compound contain Ge to increase the number of elements. Given that Mg₂Si or Mg₂Sn has an ideal crystal lattice, replacing a different element therewith is equivalent to introducing a defect thereto. That is, the crystal lattice of the quaternary compound is likely to be disturbed as compared with the ternary compound. In general, the thermal conduction includes thermal conduction by the carriers and thermal conduction by the lattice. In this system, the thermal conduction by the lattice is predominant. For this reason, by employing the quaternary compound, the crystal lattice is disturbed and the thermal conductivity is reduced.

The dimensionless figure of merit ZT of the thermoelectric material is expressed as follows. Here, a represents the Seebeck coefficient, T represents the absolute temperature, p represents the electrical resistivity and κ represents the thermal conductivity.

ZT=α²T/pκ (2)

Therefore, reducing the thermal conductivity by employing the quaternary compound leads to an enhancement of thermoelectric performance.

In the compound represented by the above general formula (1), the composition A of Mg is 1.98≦A≦2.01. As represented by Mg₂Si or Mg₂Sn, the composition A of Mg is 2.00 in terms of the stoichiometric composition ratio. However, some compositional deviations can be allowed in the crystal structure, and crystal structures up to that range can be employed. When the composition A of Mg exceeds the upper limit value, a metallic simple substance of Mg or Mg compound segregates, thereby lowering the thermoelectric performance. This can also be confirmed from FIG. 4 of Patent Document 2 and the like.

Further, in the compound represented by the above general formula (1), the composition X of Si, the composition Y of Sn and the composition Z of Ge satisfy relationships represented by formulas: 0.00<X≦0.25, 0.60≦Y≦0.95, Z>0, X+Y+Z=1 and −1.00X+0.40≧Z≧−2.00X+0.10 (0.00<X≦0.25), −1.00Y+1.00≧Z≧−1.00Y+0.75 (0.60≦Y≦0.90), −2.00Y+1.90≧Z≧−1.00Y+0.75 (0.90<Y≦0.95).

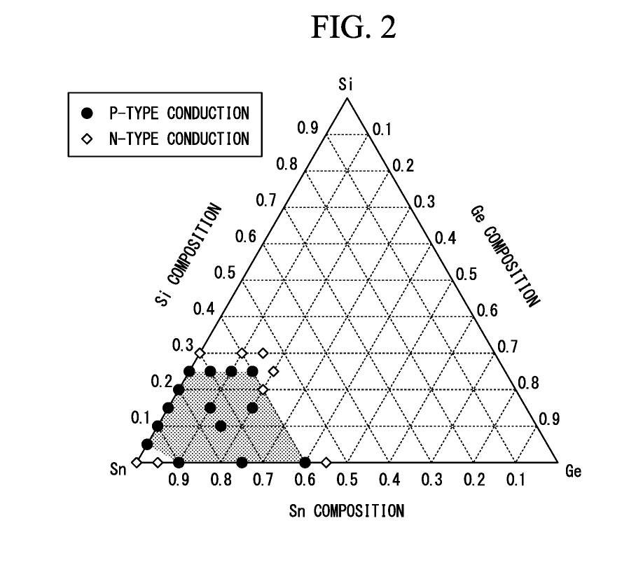

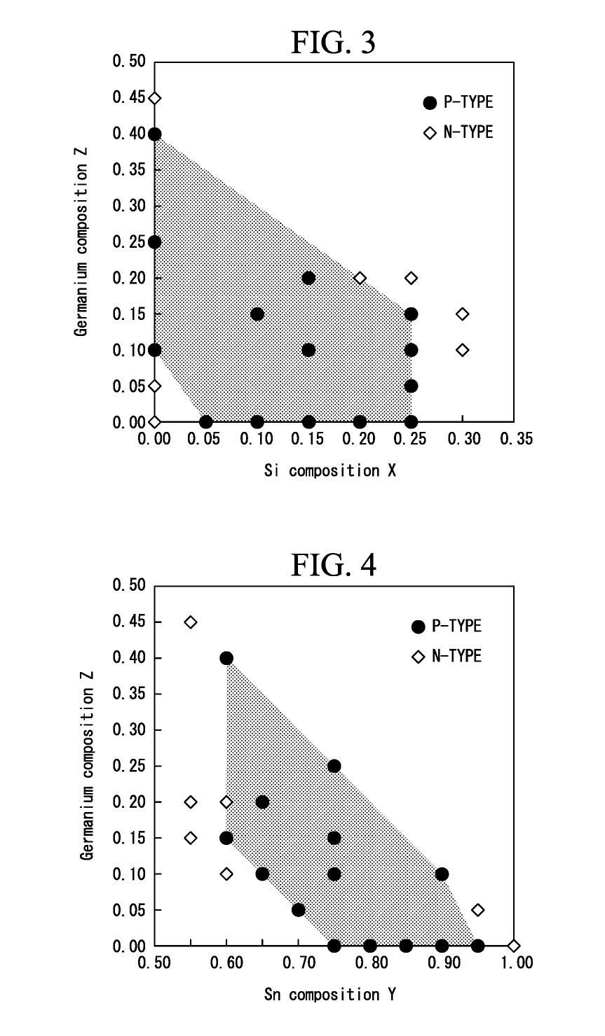

FIG. 2 is a diagram showing composition regions exhibiting p-type conduction and n-type conduction in a quaternary compound of Mg, Si, Sn and Ge. FIG. 3 shows a relationship between the compositions of Ge and Si with respect to the conduction types, and FIG. 4 shows a relationship between the compositions of Ge and Sn with respect to the conduction types.

Such composition regions are thought to occur because the quaternary compound is a solid solution of Mg₂Si, Mg₂Sn and Mg₂Ge and is influenced by the conduction type in each solid solution.

It has already been reported that Mg₂Si is n-type, Mg₂Sn is p-type and Mg₂Ge is n-type. For this reason, in the composition region where the Si content is high, it shows n-type conduction under the influence of Mg₂Si, whereas in the composition region where the Sn content is high, it shows p-type conduction under the influence of Mg₂Sn. In the conventional Mg₂(Si₁₋ₓSnₓ) system, its conduction type is determined by the influence of Mg₂Si and Mg₂Sn, but Si or Sn is further substituted with Ge in the quaternary system. Therefore, it is likely to exhibit p-type conduction when Si is substituted with Ge, and it is likely to exhibit n-type conduction when Sn is substituted with Ge.

In the thermoelectric material according to one aspect of the present invention, at least any one of the Mg site, the Si site, the Sn site and/or the Ge site of the compound represented by the general formula (1) is substituted with any one or more elements selected from the group consisting of alkali metals of group 1A and gold (Au), silver (Ag), copper (Cu), zinc (Zn), calcium (Ca) and gallium (Ga) of group 1B. The element to be substituted is preferably any one or more elements selected from the group consisting of alkali metals of group 1A and silver (Ag), zinc (Zn), calcium (Ca) and gallium (Ga) of group 1B, and more preferably silver (Ag) of Group 1B. By replacing at least any one of the Mg site, the Si site, the Sn site and/or the Ge site of the compound with these substitution elements, thermoelectric properties can be enhanced. The element to be substituted is not limited to a single element, and a plurality of elements may be substituted.

The substitution site of gallium (Ga) is different from those of alkali metals of group 1A and gold (Au), silver (Ag), copper (Cu), zinc (Zn) and calcium (Ca) of group 1B. Alkali metals of group 1A and gold (Au), silver (Ag), copper (Cu), zinc (Zn) and calcium (Ca) of group 1B substitute for the Mg site, whereas gallium (Ga) substitutes for any one of the Si site, the Sn site or the Ge site.

That is, the composition formula of a compound obtained after replacing Mg in the compound of the composition formula (1) with alkali metals of group 1A and gold (Au), silver (Ag), copper (Cu), zinc (Zn), calcium (Ca) of group 1B is represented by the following composition formula (3):

Mg_{A-B}D_{B}(Si_{X}Sn_{Y}Ge_{Z}) (3)

D is any one or more elements selected from gold (Au), silver (Ag), copper (Cu), zinc (Zn) and calcium (Ca) of group 1B. B is preferably from 0.005 to 0.05.

On the other hand, the composition formula of a compound obtained after replacing any one of the Si site, the Sn site or the Ge site in the compound of the composition formula (1) with Ga is represented by the following composition formula (4):

Mg_{A}(Ga_{B}Si_{S}Sn_{T}Ge_{U}) (4)

Here, since any one of the Si site, the Sn site or the Ge site is replaced with Ga, B+S+T+U is 1.0. Also in this case, B is preferably from 0.005 to 0.05.

When the divalent Mg of the compound of the composition formula (1) is substituted with a monovalent alkali metal, Au, Ag or Cu, an electron necessary for the bonding becomes deficient and a hole is supplied. That is, the compound of the composition formula (3) is one in which this hole is supplied to the compound of the composition formula (1), and the electrical resistivity as a semiconductor is reduced. When the electrical resistivity is reduced, the thermoelectric performance is enhanced from the general formula (2). Further, monovalent alkali metals and Ag are preferable because high thermoelectric performance can be realized, and Ag is more preferable because particularly high thermoelectric performance can be realized.

When the divalent Mg of the compound of the composition formula (1) is substituted with Zn and/or Ca, carriers are not introduced because Zn and Ca are divalent. However, it has been confirmed that the compound of the composition formula (3) can enhance the thermoelectric performance, as compared with the compound of the composition formula (1).

It is thought that this is because Zn and Ca elements are metal elements originally having a low electrical resistivity, the thermoelectric performance can be enhanced. Although the Seebeck coefficient does not change since the carrier concentration does not increase, the electrical resistivity can be reduced by the metallic properties and the thermoelectric performance can be enhanced.

The added amount of the element to be substituted is preferably from 5,000 ppm to 50,000 ppm. When these amounts are added, the number of atoms in the composition formula in the Mg₂Si type crystal structure will be from 0.005 to 0.05. In other words, B in the composition formulas (3) and (4) is from 0.005 to 0.05, more preferably from 10,000 ppm to 30,000 ppm, and still more preferably from 20,000 ppm to 30,000 ppm.

If the added amount of the substitution element is too large, the substitution element itself or its compound segregates metallically and it becomes difficult to realize high thermoelectric performance. If the added amount of the substitution element is too small, it is difficult to sufficiently lower the electrical resistivity, and it becomes difficult to realize high thermoelectric performance.

In general, the Si site, the Sn site or the Ge site of the compound of the composition formula (1) are each tetravalent. On the other hand, Ga is capable of adopting a trivalent state. For this reason, the compound of the composition formula (4) in which any one of the Si site, the Sn site and the Ge site of the compound of the composition formula (1) is substituted with Ga has a carrier, can reduce the electrical resistivity, and can enhance the thermoelectric performance

There is a Seebeck coefficient α as a parameter for enhancing the thermoelectric performance expressed by the general formula (2). The Seebeck coefficient α can be expressed by the following formula (5).

$$\begin{matrix}[ Equation 1 ] & \\ α = \frac{{k}_{B}}{e} [ log ( \frac{N}{n} ) + C ] & ( 5 )\end{matrix}$$

Here, k_{B} is the Boltzmann coefficient, e is the electric charge, C is a constant, n is the carrier concentration, and N is expressed by the following formula (6).

$$\begin{matrix}[ Equation 2 ] & \\ N = \frac{2 {( 2 π {mk}_{B} T )}^{\frac{3}{2}}}{{h}^{3}} & ( 6 )\end{matrix}$$

Here, k_{B} is the Boltzmann coefficient, h is the Planck's constant, T is the absolute temperature, and m is the effective mass. That is, the Seebeck coefficient can be expressed as a function of carrier concentration and effective mass.

The p-type thermoelectric material according to one aspect of the present invention is a quaternary compound, and a portion thereof is substituted, so that the effective mass can be increased. Therefore, the p-type thermoelectric material according to one aspect of the present invention can realize not only the improvement of the thermoelectric performance accompanying the reduction of the thermal conductivity and the electrical resistivity but also the improvement of the thermoelectric performance accompanying the increase of the Seebeck coefficient. In other words, a thermoelectric material having high thermoelectric performance can be obtained.

The thermoelectric material according to one aspect of the present invention can be used for, for example, a p-type thermoelectric element (thermoelectric semiconductor) in a thermoelectric conversion device.

(Method for Producing p-Type Thermoelectric Material)

A method for producing a p-type thermoelectric material according to one aspect of the present invention includes a step of accommodating magnesium (Mg), silicon (Si), tin (Sn), germanium (Ge) and at least any one of the group consisting of alkali metals of group 1A and gold (Au), silver (Ag), copper (Cu), zinc (Zn), calcium (Ca) and gallium (Ga) of group 1B as a substitution element in a heating member; a step of heating the aforementioned heating member to synthesize a solid solution; and a step of pulverizing and further pressurizing and sintering the aforementioned solid solution. According to this production method, it is possible to produce a thermoelectric material in which any one of the Mg site, the Si site, the Sn site and/or the Ge site of a compound represented by the following general formula (1) composed of magnesium (Mg), silicon (Si), tin (Sn) and germanium (Ge) is substituted with the aforementioned substitution element.

Mg_{A}(Si_{X}Sn_{Y}Ge_{Z}) (1)

provided that relationships represented by formulas: 1.98≦A≦2.01, 0.00<X≦0.25, 0.60≦Y≦0.95, Z>0, X+Y+Z=1 and −1.00X+0.40≧Z≧−2.00X+0.10 (0.00<X≦0.25), −1.00Y+1.00≧Z≧−1.00Y+0.75 (0.60≦Y≦0.90), −2.00Y+1.90≧Z≧−1.00Y+0.75 (0.90<Y≦0.95) are satisfied.

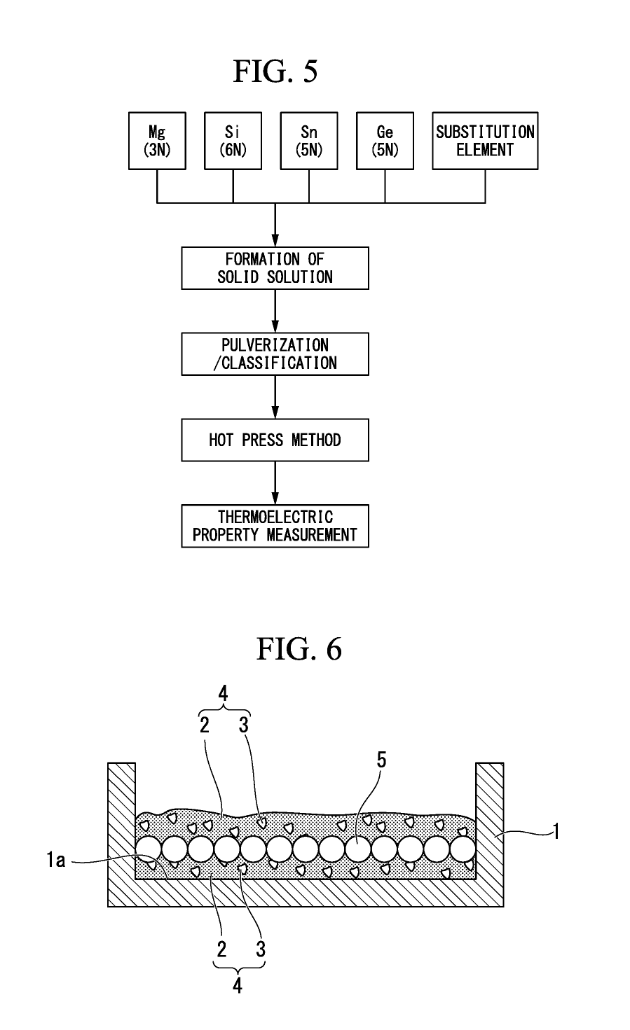

FIG. 5 is a flowchart showing a procedure of the method for producing the p-type thermoelectric material of the present invention.

First, simple substances of Mg, Si, Sn, Ge and substitution elements are weighed so as to satisfy the above composition ranges. At this time, the size of Mg is preferably from 3 to 5 mm. If the size is too large, Mg is difficult to melt, and there is a possibility that the simple substance of Mg will remain. If the size is too small, the surface area to be oxidized in the atmosphere increases and the amount of incorporated oxides of Mg increases.

Si and Ge are preferably used in the form of powders or granules, and fine powders of about several tens of micrometers are preferable. Sn is preferably granular, and its average particle diameter can range from, for example, 1 to 3 mm. It is preferable to add the substitution element in a powder form.

When an alkali metal is used as a substitution element, handling is difficult because alkali metals in the form of simple substance are very highly reactive. Therefore, it is preferable to use in the form of a salt of an organic acid (for example, a carboxylic acid). For example, when lithium is used as the alkali metal, it is preferable to use lithium acetate, lithium stearate or the like.

The amounts of Mg, Si, Sn, Ge and substitution elements to be used are determined so that the composition ratio satisfies the aforementioned formula (1).

As shown in FIG. 6, a heating member 1 is prepared. As the heating member 1, a carbon board, a crucible or the like can be used. It is desirable that the heating member 1 be baked in advance.

A mixture 4 composed of a powder mixture 2 consisting of Si, Ge and (a) substitution element(s) and Sn in the form of granules which is denoted with a reference number 3 is evenly spread over a bottom surface 1a of the heating member 1.

Mg in the form of granules which is denoted with a reference number 5 is placed on this mixture 4. The Mg granules 5 are preferably arranged on the mixture 4 at equal intervals.

Next, the mixture 4 is spread evenly thereon.

The heating means 1 and each material contained therein are heated in a heating furnace. By this heating, a solid solution of each element is prepared. As a method of preparing the solid solution, a solid phase reaction method, a liquid-solid phase reaction method, a direct melting method, a mechanical alloying method or the like can be used. In particular, a liquid-solid phase reaction method is preferable. The liquid-solid phase reaction method is a method of promoting a chemical reaction in a state where some elements are in a solid state while the other elements are in a molten state. This method is superior to other methods in that it is a simple synthesis method without composition deviation, incorporation of impurities and dust explosion. In the case of the method for producing a p-type thermoelectric material according to one aspect of the present invention, Sn, Mg, Ge and substitution elements melt to form a liquid, and Si reacts in a solid state.

The heating temperature is preferably 800° C. or higher, for example, from 800 to 1,100° C. The heating time can be set, for example, from 1 to 10 hours. With this temperature range, other elements can be melted sufficiently while Si is maintained in a solid state, and segregation of each element or the like can be suppressed. Further, with this heating time, it is possible to allow the reaction to proceed sufficiently.

In order to prevent oxidation of raw materials, heating is preferably performed in a non-oxidizing atmosphere. For example, it is desirable to perform the process in an inert gas atmosphere such as argon (Ar) or in a mixed gas atmosphere in which hydrogen (H₂) is mixed with an inert gas.

As a result, an alloy which is a solid solution containing Mg₂Si, Mg₂Sn, Mg₂Ge and a substitution element is synthesized.

The alloy is then ground. Examples of the grinding means include a hammer mill, a jaw crusher, an impact crusher, a ball mill, an attritor and a jet mill.

It is preferable to classify the obtained powder and to use one having an average particle size within a predetermined range, for example, one having an average particle size of 38 to 75 μm. As a classification method, there are an air flow classification method, a sieving method and the like.

The average particle size may be, for example, a 50% cumulative particle size in the volume-based particle size distribution. The average particle diameter can be measured by a laser diffraction type particle size analyzer or the like.

Next, this powder is pressed by hot pressing or the like and sintered. For example, the powder can be filled into a die and pressed with a punch.

The temperature condition at the time of sintering is preferably from 600 to 800° C. The pressurization condition (pressing pressure) is preferably from 10 to 100 MPa. The atmosphere during sintering is preferably an inert gas atmosphere such as argon (Ar). The pressurization time can be set, for example, from 1 to 10 hours.

The powder becomes a densified sintered body by pressurization. In addition to the above method, there are a hot isostatic pressing (HIP) process, a plasma sintering (SPS or PAS) method and the like as a sintering method.

The obtained sintered body is a thermoelectric material excellent in characteristics as a p-type thermoelectric material.

The sintered body is cut into a predetermined size depending on the purpose and polished, and then the thermoelectric properties can be measured.

### EXAMPLES

### Example 1

Mg granules (purity: 99.9%), a Si powder (99.9999%), a Sn powder (99.999%), a Ge powder (99.999%) and a Ag powder (99.99%) were prepared as raw materials.

These were weighed in accordance with the composition ratio, arranged in a carbon board and charged into a synthesis furnace to prepare an alloy composed of a solid solution. The alloy composed of the solid solution was prepared by a liquid-solid phase reaction method. The synthesis temperature was 1103 K (830° C.), the synthesis time was 4 hours and the reaction atmosphere was a reducing atmosphere of Ar+3% H₂.

Subsequently, the obtained alloy was pulverized and classified so that the particle diameter d was 38 μm≦d≦75 μm. The classified powder was sintered by hot pressing to prepare a sintered body. The sintering temperature for the sintered body was 933 K (660° C.), the sintering time was 3 hours, the sintering pressure was 50 MPa and the reaction atmosphere was an Ar atmosphere.

According to the procedure described above, a thermoelectric material represented by a composition formula of Mg_{1.975}Ag_{0.025}(Si_{0.25}Sn_{0.65}Ge_{0.10}) was obtained. At this time, the amount of Ag added as a substitution element was 25,000 ppm.

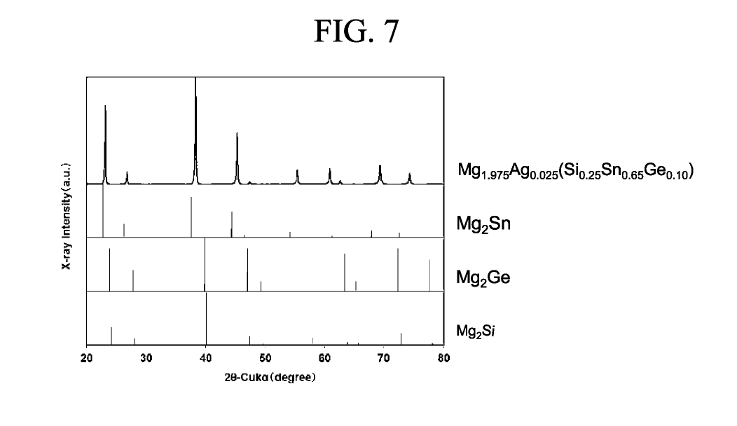

FIG. 7 shows the X-ray diffraction measurement results of the thermoelectric material of Example 1. For the X-ray diffraction measurement, RINT 2500 manufactured by Rigaku Corporation was used. Measurement conditions were set by using Cu-k_{α} rays so that the tube voltage was 40 kV, the tube current was 300 mA, and 2θ was from 10° to 90°.

The thermoelectric material of Example 1 has an inverse fluorite structure (space group: Fm3m) since its X-ray diffraction profile is located between the X-ray diffraction profiles of Mg₂Si and Mg₂Sn as shown in FIG. 7. Further, it is a single phase of Mg₂(SiSnGe) composition.

### Comparative Example 1

A thermoelectric material was prepared in the same manner as in Example 1 except that Ge was not added to the raw material. The composition formula of the thermoelectric material was Mg_{1.975}Ag_{0.025}(Si_{0.25}Sn_{0.75}). At this time, the amount of Ag added as a substitution element was 25,000 ppm.

### Comparative Example 2

A thermoelectric material was prepared in the same manner as in Example 1 except that Ag as a substitution element was not added to the raw material. The composition formula of the thermoelectric material was Mg_{2.00}(Si_{0.25}Sn_{0.65}Ge_{0.10}).

### Comparative Examples 3 to 6

They are different from Comparative Example 2 only in that the raw material ratio was changed. The composition formulae of the thermoelectric materials are as follows.

### Comparative Example 3

Mg_{2.00}(Si_{0.15}Sn_{0.75}Ge_{0.10})

### Comparative Example 4

Mg_{2.00}(Si_{0.30}Sn_{0.60}Ge_{0.10})

### Comparative Example 5

Mg_{2.00}(Sn_{0.90}Ge_{0.10})

### Comparative Example 6

Mg_{2.00}(Si_{0.90}Ge_{0.10})

### (Measurement of Electrical Resistivity)

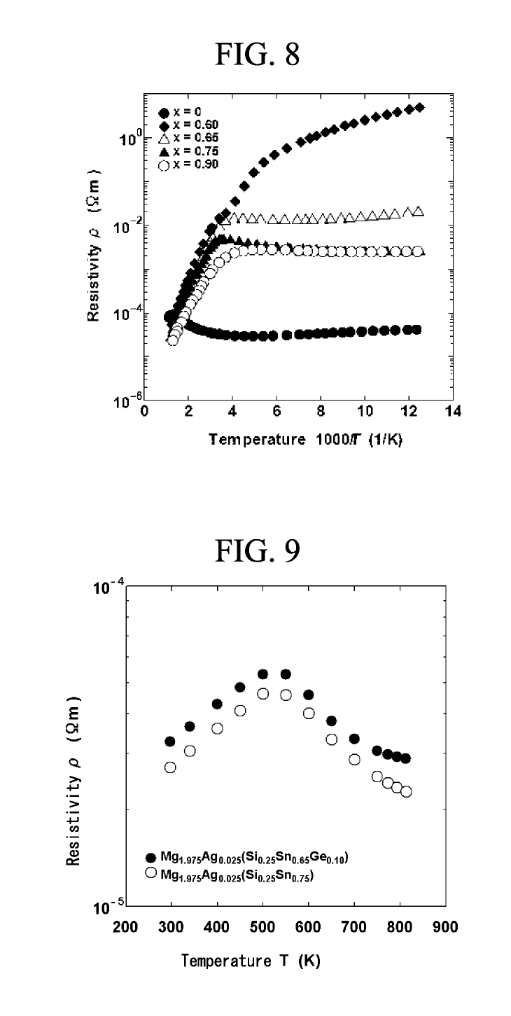

The electrical resistivity of each of Example 1 and Comparative Examples 1 to 6 was measured. The electrical resistivity was measured using the direct current four terminal method. FIG. 8 shows the measurement results of the electrical resistivity of Comparative Examples 2 to 6, and FIG. 9 shows the measurement results of the electrical resistivity of Example 1 and Comparative Example 1. In FIG. 8, x corresponds to the value of x when the thermoelectric materials of Comparative Examples 2 to 6 are expressed by the composition formula Mg_{2.00}(Si_{0.90-x}SnₓGe_{0.10}).

By comparing FIG. 8 with FIG. 9, it is clear that the electrical resistivity is reduced in Example 1 and Comparative Example 1 in which a substitution element has been added.

### (Measurement of Thermal Conductivity)

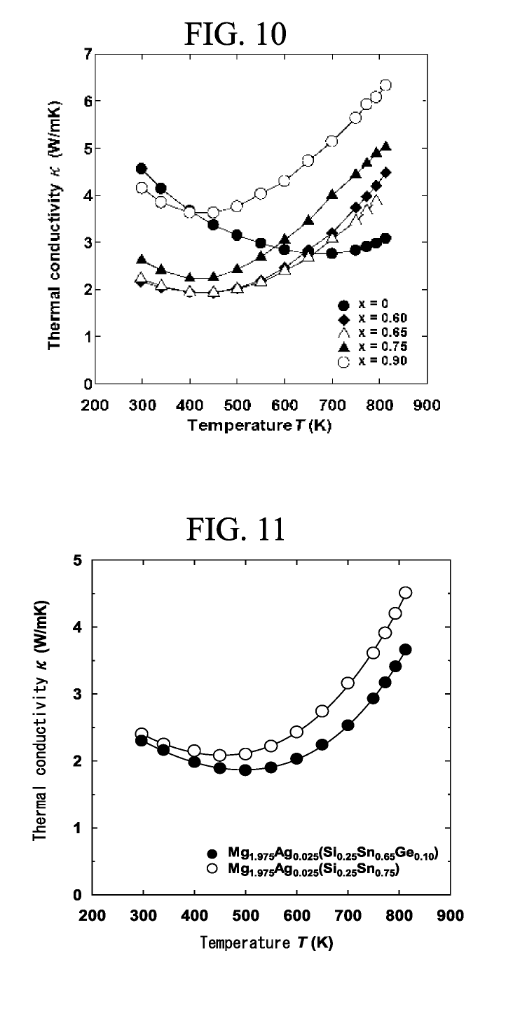

The thermal conductivity of each of Example 1 and Comparative Examples 1 to 6 was measured. The thermal conductivity was measured using a static comparison method with quartz (κ=1.37 W/mK). The temperature dependence of thermal conductivity was measured using a laser flash method (ULVAC-RIKO, Inc.; TC-7000). FIG. 10 shows the measurement results of the thermal conductivities of Comparative Examples 2 to 6, and FIG. 11 shows the measurement results of the thermal conductivities of Example 1 and Comparative Example 1. In FIG. 10, x is the same as in FIG. 8.

As shown in FIG. 11, Example 1 shows lower thermal conductivity than that of Comparative Example 1 in the entire temperature range. Further, when comparing the result of Comparative Example 2 (x=0.65) in FIG. 10 with the result of Example 1 in FIG. 11, there is no great difference in the thermal conductivity. In other words, the thermal conductivity decreases as the thermoelectric material is replaced with one composed of a quaternary compound.

### (Measurement of Seebeck Coefficient)

The Seebeck coefficient of each of Example 1 and Comparative Examples 1 to 6 was measured. The Seebeck coefficient at room temperature was calculated from the thermoelectromotive force obtained by the temperature difference within 2 K, and the temperature dependence was measured using the large temperature difference method.

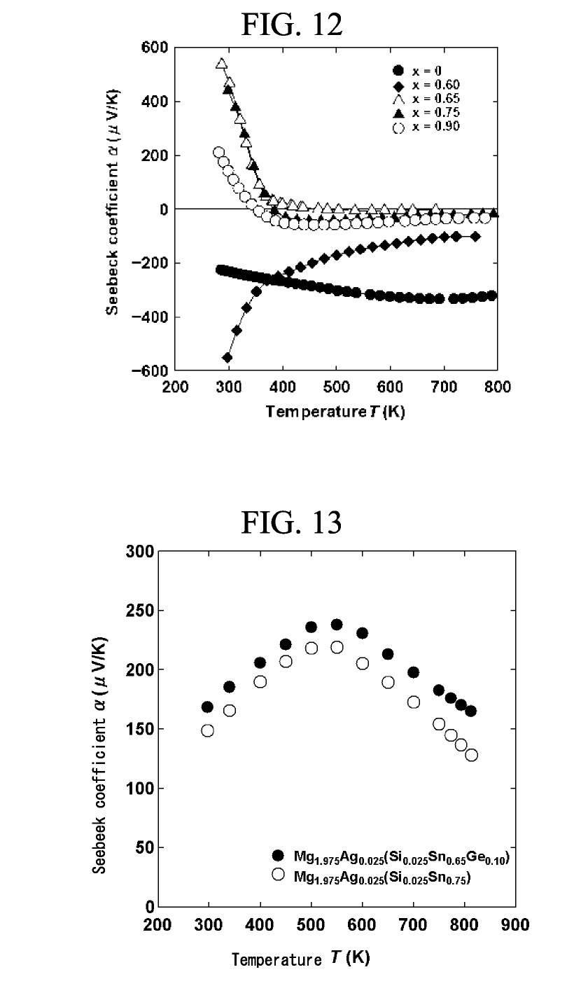

FIG. 12 shows the measurement results of the Seebeck coefficients of Comparative Examples 2 to 6, and FIG. 13 shows the measurement results of the Seebeck coefficients of Example 1 and Comparative Example 1. In FIG. 12, x is the same as in FIG. 8.

By comparing FIG. 12 with FIG. 13, it is clear that the temperature dependence of the Seebeck coefficient greatly differs. As shown in FIG. 12, in Comparative Examples 2 to 6 in which no substitution element has been added, the Seebeck coefficient approaches 0 as the temperature rises. It is thought that this is because as the temperature rises, electrons in the semiconductor forming the thermoelectric material are thermally excited from the valence band to the conduction band, and holes generated as a result of the removal of thermally excited electrons and electrons in the valence band are increased rapidly and form an intrinsic region. Therefore, the thermoelectric materials of Comparative Examples 2 to 6 are reversed from p-type conduction to n-type conduction as the temperature rises. In other words, they cannot function as stable p-type thermoelectric materials.

On the other hand, as shown in FIG. 13, in Example 1 and Comparative Example 1 in which a substitution element has been added, thermoelectric materials of p-type conduction that are also stable with respect to the temperature can be obtained. The thermoelectric material of Example 1 shows a high Seebeck coefficient, as compared with the thermoelectric material of Comparative Example 1.

### (Measurement of Dimensionless Figure of Merit)

The dimensionless figure of merit is obtained by multiplying the performance index Z of the thermoelectric material by the absolute temperature and is generally expressed as ZT. As indicated by the general formula (2), ZT can be obtained from the thermal conductivity, electrical resistivity, and Seebeck coefficient measured as described above.

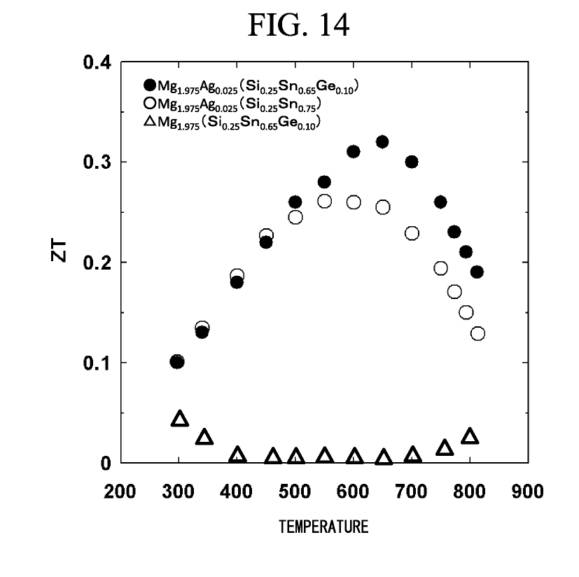

FIG. 14 shows the measurement results of the dimensionless figure of merit ZT of Example 1, Comparative Example 1 and Comparative Example 2.

Example 1 and Comparative Example 1 in which a substitution element has been added show higher thermoelectric performance, as compared with Comparative Example 2. It is considered that although the dimensionless thermoelectric performance is low in Comparative Example 2 because sufficient carriers are not present, in Example 1 and Comparative Example 1, the dimensionless thermoelectric performance is increased due to the decrease in electrical resistivity as carriers are introduced by the substitution. In addition, Example 1 shows higher thermoelectric performance as compared with Comparative Example 1. The maximum value is 0.28 at 650 K in Example 1, whereas it is 0.26 at 550 K in Comparative Example 1. In Example 1, the thermoelectric performance can be improved by 8% as compared with Comparative Example 1.

As described above, in Comparative Examples 2 to 4 in which quaternary compounds are used among Comparative Examples 2 to 6, no significant difference is observed in each measurement result. That is, since substantially the same results are obtained even when the composition ratio is changed, also in Example 1, high thermoelectric performance can be exhibited even if the composition ratio is changed within a predetermined range.

### Example 2

Example 2 is different from Example 1 only in that Ag as a raw material is replaced by Ga.

That is, any one of the Si, Sn and Ge sites in a quaternary composition of Mg_{2.00}(Si_{0.25}Sn_{0.65}Ge_{0.10}) was substituted with the added Ga (added amount: 25,000 ppm). The composition formula of the obtained composition is Mg_{2.00}(Ga_{0.025}Si_{0.25-α}Sn_{0.65-β}Ge_{0.10-γ}). Here, α, β and γ satisfy the relationships represented as α≧0, β≧0, γ≧0 and α+β+γ=0.025.

### Example 3

Example 3 is different from Example 1 in that Li is added as a raw material. That is, the Mg site of the quaternary composition of Mg_{2.00}(Si_{0.25}Sn_{0.65}Ge_{0.10}) was substituted with the added Ag (added amount: 20,000 ppm) and Li (added amount: 5,000 ppm). The composition formula of the obtained composition is Mg_{1.975}Ag_{0.020}Li_{0.005}(Si_{0.25}Sn_{0.65}Ge_{0.10}).

### Example 4

Example 4 is different from Example 1 in that Li and Ga are added as raw materials. That is, the Mg site of the quaternary composition of Mg_{2.00}(Si_{0.25}Sn_{0.65}Ge_{0.10}) was substituted with the added Ag (added amount: 20,000 ppm) and Li (added amount: 5,000 ppm), and any one of the Si, Sn and Ge sites was substituted with the added Ga (added amount: 25,000 ppm). The composition formula of the obtained composition is Mg_{1.975}Ag_{0.020}Li_{0.005}(Ga_{0.025}Si_{0.25-α}Sn_{0.65-β}Ge_{0.10-γ}). Here, α, β and γ satisfy the relationships represented as α≧0, β≧0, γ≧0 and α+β+γ=0.025.

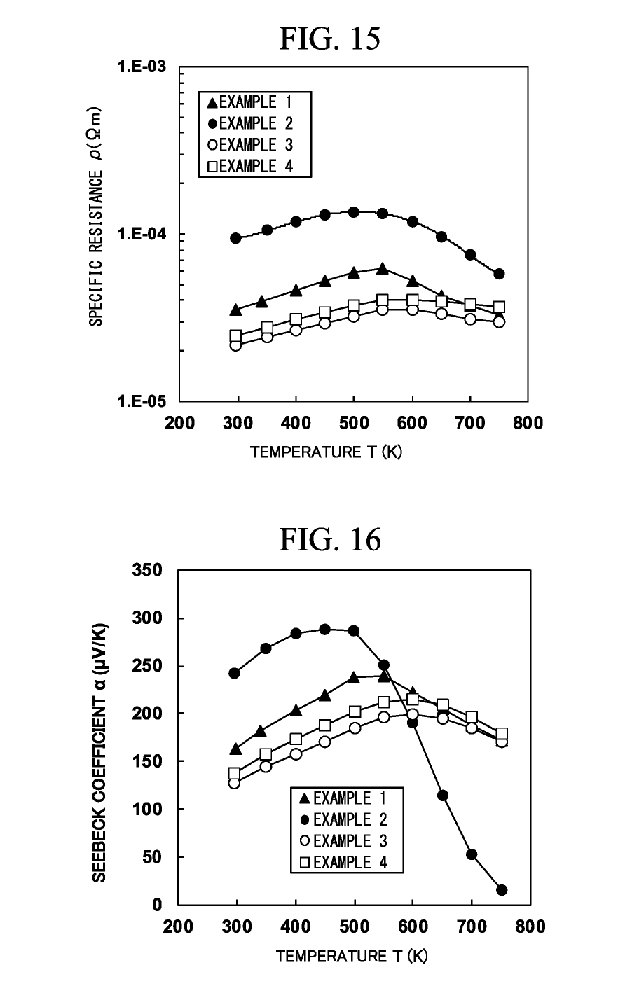

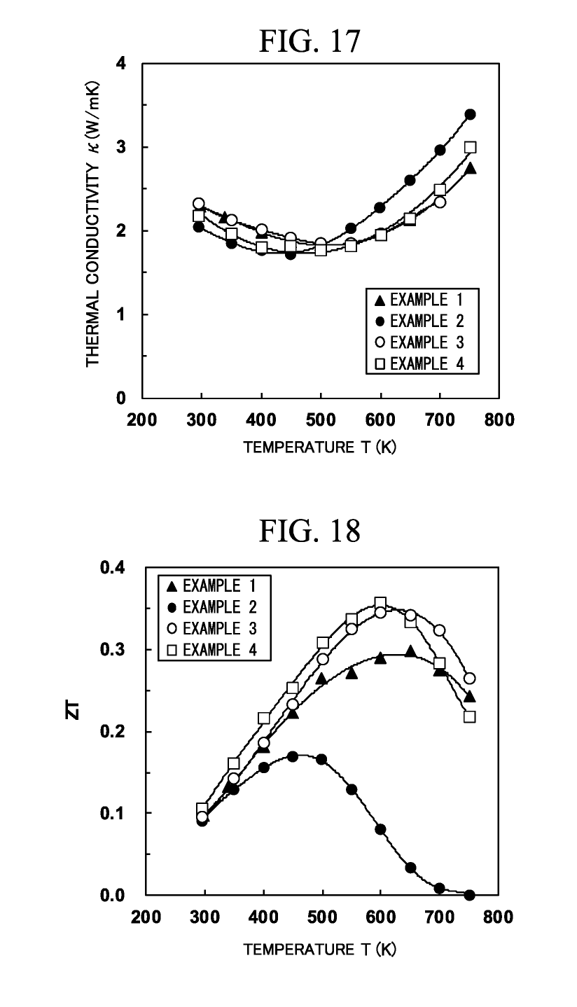

The electrical resistivity, Seebeck coefficient, thermal conductivity, and dimensionless figure of merit (ZT) of Examples 1 to 4 were measured by the same means as described above. The measured results are shown in FIGS. 15 to 18.

From the results of FIG. 15 to FIG. 18, it can be confirmed that the p-type performance is exhibited in any of Examples 1 to 4. In addition, Examples 3 and 4 in which the Mg site was replaced with two or more added elements show better thermoelectric properties as compared to those of Examples 1 and 2. It is thought that this is because the uniformity of the thermoelectric material was enhanced by adding two or more elements. It is thought that as the number of added elements increases, as compared with the case where only one element is added, the segregation of elements is reduced and the uniformity increases.

### REFERENCE SIGNS LIST

1: Heating member; 1a: Bottom surface; 2: Powder mixture; 3: Sn; 4: Mixture; 5: Mg

1. A p-type thermoelectric material,
wherein at least any one of a Mg site, a Si site, a Sn site and/or a Ge site of a compound represented by the following general formula (1) which is composed of magnesium (Mg), silicon (Si), tin (Sn) and germanium (Ge) is substituted with any one or more elements selected from the group consisting of alkali metals of group 1A and gold (Au), silver (Ag), copper (Cu), zinc (Zn), calcium (Ca) and gallium (Ga) of group 1B:
Mg_{A}(Si_{X}Sn_{Y}Ge_{Z}) (1)
provided that relationships represented by formulas:
1.98≦A≦2.01,
0.00<X≦0.25, 0.60≦Y≦0.95, Z>0, X+Y+Z=1,
and
−1.00X+0.40≧Z≧−2.00X+0.10(0.00<X≦0.25), −1.00Y+1.00≧Z≧−1.00Y+0.75(0.60≦Y≦0.90), −2.00Y+1.90≧Z≧−1.00Y+0.75(0.90<Y≦0.95)
are satisfied.

2. The p-type thermoelectric material according to claim 1,
wherein the compound represented by said general formula (1) is multiply substituted with silver (Ag) and an alkali metal of group 1A and/or gold (Au), copper (Cu), zinc (Zn), calcium (Ca) and gallium (Ga) of group 1B.

3. The p-type thermoelectric material according to claim 1, wherein an element to be substituted is silver (Ag).

4. The p-type thermoelectric material according to claim 1, wherein an element to be substituted is added at 5,000 ppm to 50,000 ppm.

5. The p-type thermoelectric material according to claim 1,
wherein at least any one of the Mg site, the Si site, the Sn site and/or the Ge site of the compound represented by said general formula (1) is substituted with any two or more elements selected from the group consisting of alkali metals of group 1A and gold (Au), silver (Ag), copper (Cu), zinc (Zn), calcium (Ca) and gallium (Ga) of group 1B.

6. A method for producing a p-type thermoelectric material, the method comprising:
a step of accommodating magnesium (Mg), silicon (Si), tin (Sn), germanium (Ge) and at least any one of the group consisting of alkali metals of group 1A and gold (Au), silver (Ag), copper (Cu), zinc (Zn), calcium (Ca) and gallium (Ga) of group 1B as a substitution element in a heating member;
a step of heating said heating member to synthesize a solid solution; and
a step of pulverizing and further pressurizing and sintering said solid solution,
wherein at least any one of a Mg site, a Si site, a Sn site and/or a Ge site of a compound represented by the following general formula (1) which is composed of magnesium (Mg), silicon (Si), tin (Sn) and germanium (Ge) is substituted with said substitution element,
Mg_{A}(Si_{X}Sn_{Y}Ge_{Z}) (1)
provided that relationships represented by formulas:
1.98≦A≦2.01,
0.00≦X≦0.25, 0.60≦Y≦0.95, Z>0, X+Y+Z=1,
and
−1.00X+0.40≧Z≧−2.00X+0.10(0.00<X≦0.25), −1.00Y+1.00≧Z≧−1.00Y+0.75(0.60≦Y≦0.90), −2.00Y+1.90≧Z≧−1.00Y+0.75(0.90<Y≦0.95)
are satisfied.

7. A thermoelectric element comprising the p-type thermoelectric material according to claim 1.
